(19) United States
(12) Patent Application Publication
(10) Pub. No.: US 2011/0204380 A1
(43) Pub. Date: Aug. 25, 2011

(54) NITRIDE-BASED FET

(75) Inventors: Akira YOSHIOKA, Kanagawa-ken (JP); Yasunobu Saito, Tokyo (JP); Hidetoshi Fujimoto, Kanagawa-ken (JP); Tetsuya Ohno, Kanagawa-ken (JP); Takao Noda, Tokyo (JP)

(73) Assignee: Kabushiki Kaisha Toshiba, Tokyo (JP)

(21) Appl. No.: 13/032,582

(22) Filed: Feb. 22, 2011

(30) Foreign Application Priority Data
Feb. 25, 2010 (JP) P2010-040079

(51) Int. Cl. H01L 29/772

(52) U.S. Cl. 257/76; 257/E29.242

(57) ABSTRACT

According to an embodiment, in a nitride-based FET, a protrusion portion is formed at an upper portion of an undoped GaN layer by second recess etching. On the protrusion portion, an undoped AlGaN layer is provided which is formed by first recess etching the upper portion of the undoped AlGaN layer. A multilayer portion is composed of the protrusion portion of the undoped GaN layer, the undoped AlGaN layer, and an insulating film. A trench portion is formed by recess etching the insulating film, the undoped AlGaN layer and a surface of the undoped GaN layer. A gate insulating film is formed on the multilayer portion and the trench portion. A gate electrode is formed on the gate insulating film so as to cover the trench portion. A film thickness of the insulting film is set larger than that of the gate insulating film.

### CROSS REFERENCE TO RELATED APPLICATION

This application is based upon and claims the benefit of priority from the prior Japanese Patent Application No. 2010-40079, filed on Feb. 25, 2010, the entire contents of which are incorporated herein by reference.

### FIELD

Embodiments described herein relate to a nitride-based FET (field effect transistor).

### BACKGROUND

As a nitride-based FET using GaN has a large bandgap compared with Si and has a high critical electric field, a device with high breakdown voltage, low ON resistance and low loss can be realized. In particular, a GaN HFET (Hetero junction field effect transistor) using a hetero structure of AlGaN and GaN can realize desired properties in a simple device structure. In the hetero structure of AlGaN and GaN, a high concentration of two dimensional electron gas (2DEG) can be obtained by the polarization and so on at the hetero interface of AlGaN and GaN, and as a result, it can be achieved to reduce ON resistance of the GaN HFET.

In a GaN HFET, a width of a multilayer portion formed by recess etching is reduced in order to make the GaN FET a device of an enhancement mode (normally-off type) which does not become ON state when a voltage is not applied to a gate electrode. For the reason, there is a problem that the variation in the threshold voltages (Vth) of the enhancement mode GaN HFETs increases. In addition, there is a problem that it is difficult to set the threshold voltage (Vth) of enhancement mode GaN HFET to a predetermined value, not less than 3 V, for example.

### BRIEF DESCRIPTION OF THE DRAWINGS

FIG. 1 is a plan view illustrating a nitride-based FET according to a first embodiment;

FIG. 2 is a schematic cross sectional view illustrating the nitride-based FET along a line A-A in FIG. 1;

FIG. 3 is a schematic cross sectional view illustrating the nitride-based FET along a line B-B in FIG. 1;

FIG. 4 is a schematic cross sectional view illustrating the nitride-based FET along a line C-C in FIG. 1;

FIG. 5 is a schematic cross sectional view illustrating a nitride-based FET of a comparative example according to the first embodiment;

FIG. 6 is a diagram illustrating the relation between a width of multilayer portion and a threshold voltage (Vth) according to the first embodiment; and a solid line (a) in the figure is a relation diagram of the embodiment, and a broken line (b) in the figure is a relation of the comparative example;

FIG. 7 is a schematic cross sectional view illustrating a nitride-based FET according to a second embodiment;

FIG. 8 is a diagram illustrating the relation between a width of multilayer portion and a threshold voltage (Vth) according to the second embodiment; and a solid line (a) in the figure is a relation diagram of the embodiment, and a broken line (b) in the figure is a relation diagram of the comparative example;

FIG. 9 is a diagram illustrating the variation in the threshold voltages (Vth) according to the second embodiment; and a histogram (a) in the figure is a distribution diagram of the embodiment, and a histogram (b) in the figure is a distribution diagram of the comparative example;

FIG. 10 is a plan view illustrating a nitride-based FET according to a third embodiment;

FIG. 11 is a schematic cross sectional view illustrating the nitride-based FET along a line D-D in FIG. 10;

FIG. 12 is a plan view illustrating a nitride-based FET according to a fourth embodiment;

FIG. 13 is a schematic cross sectional view illustrating the nitride-based FET along a line E-E in FIG. 12; and

FIG. 14 is a schematic cross sectional view illustrating the nitride-based FET along a line F-F in FIG. 12.

### DETAILED DESCRIPTION

According to one embodiment, a nitride-based FET includes a semiconductor substrate, a first nitride semiconductor layer, a second nitride semiconductor layer, a multilayer portion, trench portions, a gate insulating film, a gate electrode, a source electrode and a drain electrode. The first nitride semiconductor layer is formed directly or via a buffer layer on the semiconductor substrate. The second nitride semiconductor layer is formed on the first nitride semiconductor layer. The multilayer portion is formed by stacking, a protrusion portion of the first nitride semiconductor layer that is a remaining portion at an upper portion of the first nitride semiconductor layer without recess when a peripheral portion of the first nitride semiconductor layer is recessed by selective etching, the second nitride semiconductor layer whose upper portion is recessed that is formed on the protrusion portion, and an insulating film that is formed above the protrusion portion via the second nitride semiconductor layer whose upper portion is recessed by selective etching. The trench portions with stripe shape are arranged at both sides of the multilayer portion, in each of which the second nitride semiconductor layer whose upper portion is recessed is recessed by selective etching in a stripe direction so as to expose a surface of the first nitride semiconductor layer. The gate insulating film is formed at the side surface of the multilayer portion and on the multilayer portion and the trench portions and has a film thickness smaller than that of the insulating film. The gate electrode is formed on the gate insulating film. The source electrode and the drain electrode are arranged so as to face each other across the gate electrode.

Hereinafter, a plurality of further embodiments will be described with reference to the drawings. In the drawings, the same reference numerals designate the same or similar portions.

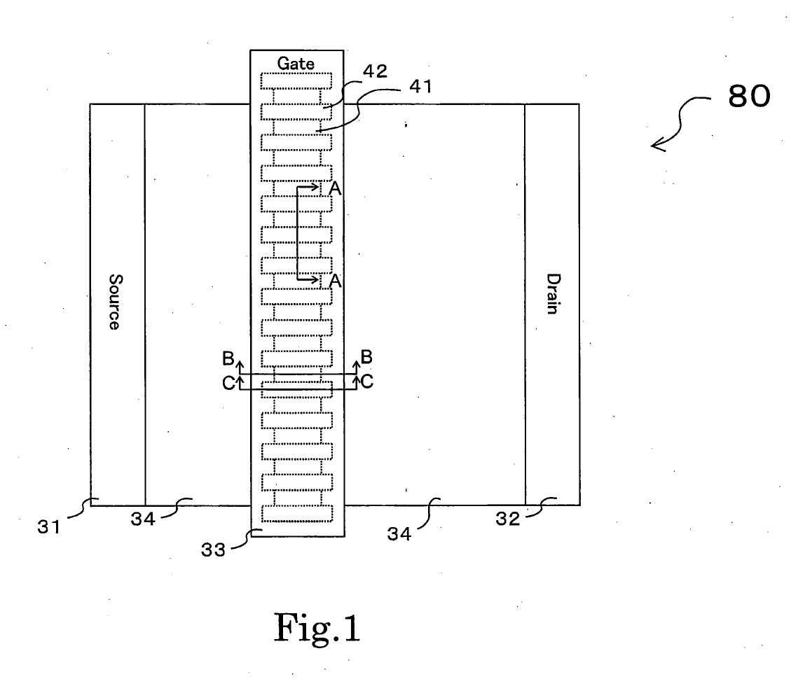

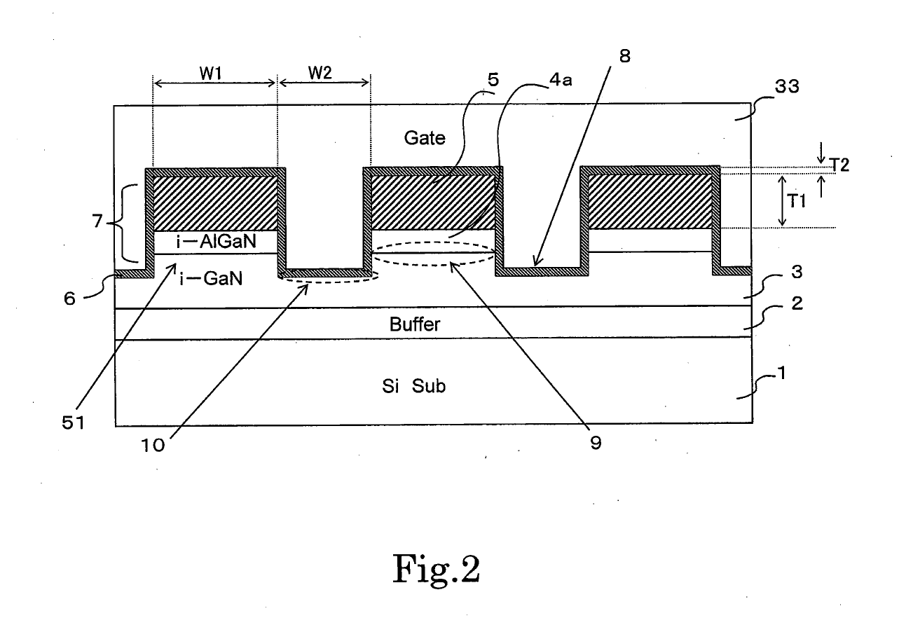

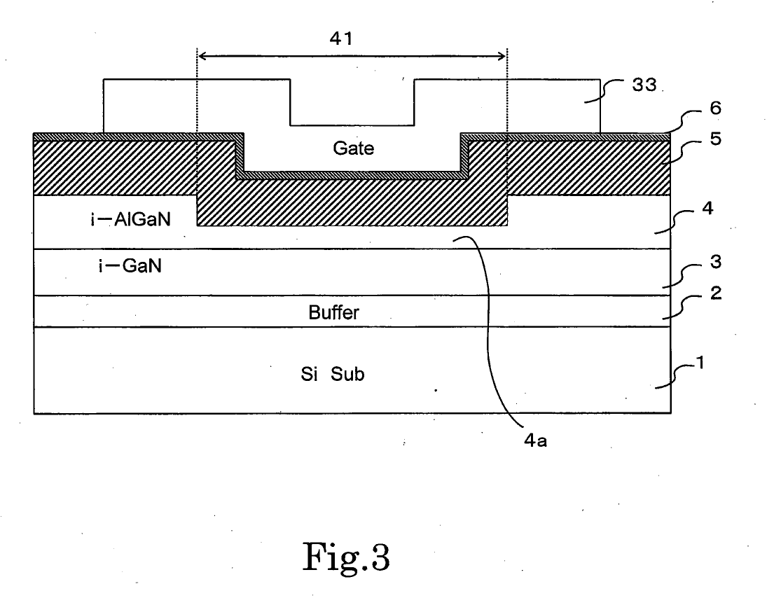

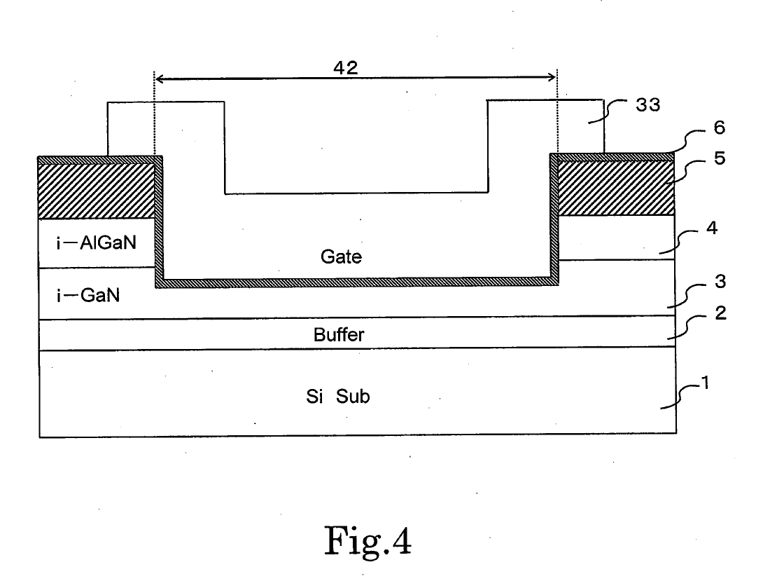

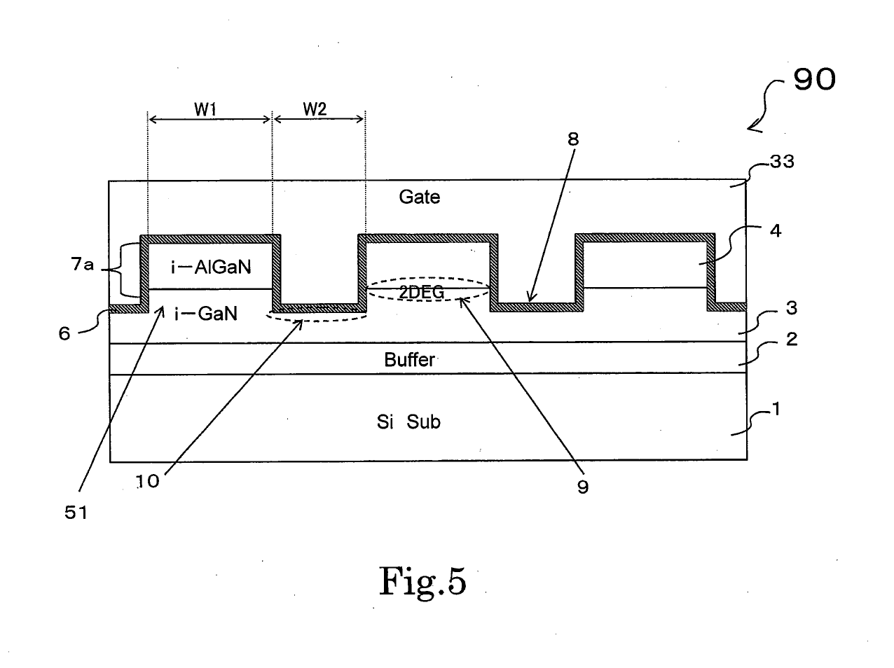

A nitride-based FET according to a first embodiment will be described with reference to the drawings. FIG. 1 is a plan view illustrating a nitride-based FET, FIG. 2 is a schematic cross sectional view illustrating the nitride-based FET along a line A-A in FIG. 1, FIG. 3 is a schematic cross sectional view illustrating the nitride-based FET along a line B-B in FIG. 1, FIG. 4 is a schematic cross sectional view illustrating the nitride-based FET along a line C-C in FIG. 1, and FIG. 5 is a schematic cross sectional view illustrating a nitride-based FET of a comparative example. In the embodiment, two kinds of recess regions with different depths are provided immediately under a gate electrode so as to make a GaN HFET a device of enhancement mode (to make the GaN HFET normally OFF type).

As shown in FIG. 1, a source electrode 31, a drain electrode 32, a gate electrode 33, and a device region 34 are provided in a nitride-based FET 80. The nitride-based FET 80 is an enhancement mode (normally OFF type) GaN HFET (Hetero junction field effect transistor). The nitride-based FET 80 has high breakdown voltage characteristics (100 to 1000V, for example), and is applied to a high power switching device.

The source electrode 31 is provided at the left end in the figure. The drain electrode 32 is provided at the right end in the figure. The gate electrode 33 is provided on the device region 34 between the source electrode 31 and the drain electrode 32 which are arranged to face each other. The source electrode 31, the drain electrode 32, the gate electrode 33, and the device region 34 are isolated from the surroundings by device isolation region (not shown).

Immediately under the gate electrode 33, recess regions (first recess regions) 41 having a rectangular structure and recess regions (second recess regions) 42 having a rectangular structure are provided. Here, each of the recess regions 42 has a construction in which a crosswise direction size of the recess regions 42 is longer than that of each of the recess regions 41, a recess depth of the recess regions 42 is deeper than that of each of the recess regions 41, and a long end portion size protrudes from that of each of the recess regions 41, respectively. The recess regions (second recess regions) 42 are arranged at the upper end portion and the lower end portion in the figure. The recess regions (second recess regions) 42 and the recess regions (first recess regions) 41 are arranged alternately and periodically in the up-and-down direction in the figure. The recess regions 41 and the recess regions 42 arranged alternately and periodically extend to the outside (device isolation region) of the device region 34 so as to divide the device region 34. In this structure, the source and the drain do not short out.

The nitride-base FET 80 is made a device of an enhancement mode (threshold voltage (Vth) is plus) by providing the recess regions 42 (second recess regions) 42 and the recess regions (first recess regions) 41 immediately under the gate electrode 33. In case that the recess regions (first recess regions) 41 are not provided, for example, it is difficult to make the nitride-based FET 80 a stably enhancement mode transistor (to make the threshold voltage (Vth) plus), by the effect of highly-concentrated two dimensional electron gas (2DEG) which is generated by polarization at the hetero interface of AlGaN and GaN.

Here, the recess regions 41 and 42 are formed by recess etching which the device region 34 is etched vertically with an RIE (Reactive Ion Etching) method using BCl₃ plasma, for example. In this RIE method, it is preferable to perform the recess etching under a low RF bias power condition (about 10 W, for example) so as to suppress the property degradation of the nitride-base FET 80 which is a GaN HFET caused by the RIE damage. In addition, it is preferable to perform an RIE post processing so as to prevent the damage and contamination which will be generated by the RIE method. The term “recess etching” means to perform wet etching or dry etching selectively a gate region and a device isolation region and so on. The recess regions 42 having the stripe shaped structure are arranged at the both sides of the recess region 41 having the stripe shaped structure. Each of the recess regions 42 has a recess depth deeper than that of the recess region 41 and end portions protruding from those of the recess region 41. By arranging the recess regions 42 with a construction like this, it is possible to suppress the mutual interference between the recess regions 41 which function as active regions.

As shown in FIG. 2, in the nitride-based FET 80, a buffer layer 2 is formed on a first main face (surface) of a silicon substrate 1 which is a semiconductor substrate. An undoped GaN layer 3 is formed on a first main face (surface) of the buffer layer 2. The buffer layer 2 is formed so as to reduce the lattice mismatch between the silicon substrate 1 and the undoped GaN layer 3. At the region of a multilayer portion 7, a protrusion portion 51 of the undoped GaN layer 3, an undoped AlGaN layer 4a, an insulating film 5, a gate insulating film 6, and the gate electrode 33 are stacked. Here, the protrusion portion 51 is formed along the direction of a gate stripe (the direction of the recess regions 41 and 42 each of which is formed in a stripe shape as shown in FIG. 1). A film thickness of the undoped AlGaN layer 4a (a second portion) with a concave structure is smaller than that of the undoped AlGaN layer 4 (a first portion). The undoped AlGaN layer 4a is formed by first recess etching which the upper portion of an undoped AlGaN layer 4 is etched. The protrusion portion 51 of the undoped GaN layer 3 is formed by second recess etching which the upper portion of the undoped GaN layer 3 is etched.

The recess region (first recess region) 41 in FIG. 1 is composed of the protrusion portion 51 of the undoped GaN layer 3, the undoped AlGaN layer 4a and the insulating film 5, and corresponds to the multilayer portion 7 having a multilayer portion width W1. At the recess region (second recess region) 42 in FIG. 1, the insulating film 5, the undoped AlGaN layer 4a and the surface of the undoped GaN layer 3 are recessed by selective etching, and the recess region (second recess region) 42 corresponds to a trench portion 8 with a trench width W2.

The gate insulating film 6 is formed on the multilayer portion 7 and the trench portion 8. The gate electrode 33 is formed on the gate insulating film 6 so as to cover the trench portion 8. The gate electrode 33 is formed with a large film thickness on the trench portion 8 and with a smaller film thickness on the multilayer portion 7 than that on the trench portion 8. A film thickness T1 of the insulating film 5 is set larger than a film thickness T2 of the gate insulating film 6

Here, the buffer layer 2, the undoped GaN layer 3, and the undoped AlGaN layer 4 are formed using an MOCVD (Metal Organic Chemical Vapor Deposition) method. A multilayer film formed by laminating a GaN layer and an MN layer alternately and repeatedly is used as the buffer layer 2. A silicon oxide film (SiO₂ film) is used as the insulating film 5, but a Low-k insulating film with a smaller dielectric constant than that of the silicon oxide film (SiO₂ film), such as an SiOC film, may be used instead. A silicon nitride film (SiN film) is used as the gate insulating film 6, but a High-k gate insulating film, such as a tantalum oxide film (Ta₂O₅ film), a hafnium oxide film (HfO₂ film) or an aluminum oxide film (Al₂O₃ film), may be used instead. A polycrystalline silicon film doped with P-type impurities is used as the gate electrode 33, but a laminated film of nickel(Ni)/gold(Au) or a laminated film of titanium(Ti)/platinum(Pt)/gold(Au) may be used instead. A laminated film of titanium(Ti)/aluminum(Al) is used as the source electrode 31 and the drain electrode 32, but a laminated film of titanium(Ti)/aluminum(Al)/nickel(Ni)/gold(Au) may be used instead.

In addition, the thickness of the undoped AlGaN layer 4a formed by recess etching which the surface of the undoped AlGaN layer 4 is etched is set so that, two dimensional electron gas (2DEG) which is generated at a interface 9 between the undoped AlGaN layer 4a and the undoped GaN layer 3 disappears when a gate voltage is not applied. At a interface 10 between the gate insulating film 6 and the undoped GaN layer 3 at the bottom of the trench portion 8, carries are not generated when a gate voltage is not applied.

Consequently, when a relatively small positive voltage is applied to the gate electrode 33, an inverted channel layer is generated at the interface 10, and the transistor becomes in ON state. In this time, as the insulating film 5 with a film thickness larger than that of the gate insulating film 6 is provided at the upper portion of the multilayer portion 7, carriers are not generated at the interface 9 because of being not affected by the voltage given from the gate electrode 33. Then, when the value of the gate voltage increases, carries are generated also at the interface 9 under the influence of the potential of the gate electrode 33 from the side surface of the multilayer portion 7. As the interface 9 is a good epitaxial interface, the mobility therein is high, and accordingly, it is possible to greatly reduce the ON resistance of the nitride-based FET 80, by giving a voltage larger than a voltage with which carries can be generated at the interface 9 to the gate electrode 33.

As shown in FIG. 3, at the both sides of the recess region (first recess region) 41 in the gate stripe direction, the buffer layer 2, the undoped GaN layer 3, the undoped AlGaN layer 4, the insulating film 5, the gate insulating film 6 and the gate electrode 33 are stacked on the silicon substrate 1. Here, extension widths of the gate electrode 33 from the recess region (first recess region) 41 at the source electrode 31 side and the drain electrode 32 side are set to the same width, but in order to reduce the current collapse and to increase high breakdown voltage characteristics of the nitride-based FET 80, the extension width of the gate electrode 33 at the drain electrode 32 side may be made larger (so-called, field plate structure).

Here, the undoped AlGaN layer 4 is set in the range represented by AlₓGa₍₁₋ₓ₎N (0<x<1). The value of x is set to 0.25, for example.

As shown in FIG. 4, at the both sides of the recess region (second recess region) 42, the buffer layer 2, the undoped GaN layer 3, the undoped AlGaN layer 4, the insulating film 5, the gate insulating film 6, and the gate electrode 33 are stacked on the silicon substrate 1. Here, extension widths of the gate electrode 33 from the recess region (second recess region) 42 at the source electrode 31 side and the drain electrode 32 side are set to the same width, but in order to reduce the current collapse and to increase high breakdown voltage characteristics of the nitride-based FET 80, the extension width of the gate electrode 33 at the drain electrode 32 side may be made larger (so-called, field plate structure).

As shown in FIG. 5, in a nitride-based FET 90 of a comparative example, the undoped AlGaN layer 4 is not recess etched by selective etching, and the insulating film 5 with a film thickness larger than that of the gate insulating film 6 is not provided on the undoped AlGaN layer 4. Specifically, a multilayer portion 7a is composed of the protrusion portion 51 of the undoped GaN layer 3 and the undoped AlGaN layer 4. It is achieved to make the nitride-based FET 90 of the comparative example a device of an enhancement mode by arbitrarily changing the trench width W2 of the trench portion 8 and the multilayer portion width W1 of the multilayer portion 7a.

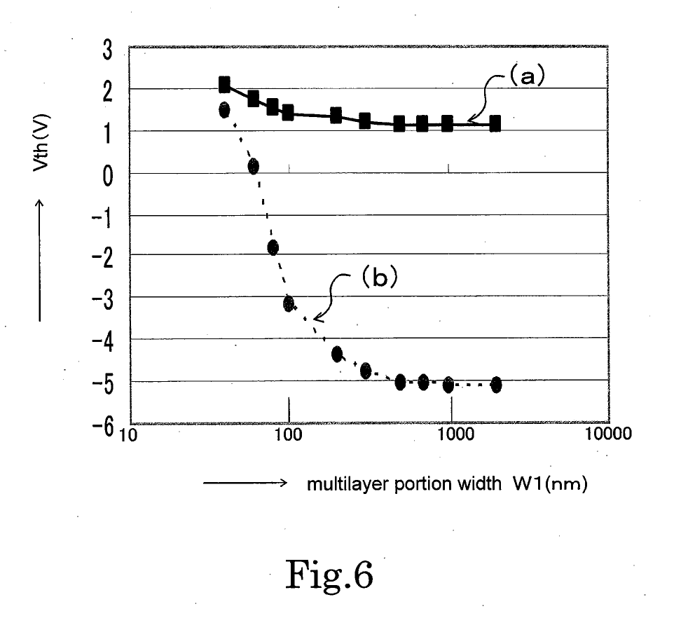

Next, DC characteristics of the nitride-based FETs will be described with reference to FIG. 6. FIG. 6 is a diagram illustrating the relation between a width of multilayer portion and a threshold voltage (Vth), and a solid line (a) in the figure is a relation diagram in the embodiment, and a broken line (b) in the figure is a relation diagram in the comparative example.

As shown in FIG. 6, a structure is employed for the nitride-based FET 80 of the embodiment shown by the solid line (a). That is, the upper portion of the undoped AlGaN layer 4 is recessed by selective etching so that the two dimensional electron gas disappears when a gate voltage is not applied, the gate stripes (protrusion portions 51) are isolated by the trench portion 8, and the trench portion 8 protrudes from the gate stripes (protrusion portions 51) so as to suppress the mutual interference between the gate stripes (protrusion portions 51). For the reason, even if the multilayer portion width W1 changes, the threshold voltage (Vth) of the nitride-based FET 80 changes extremely small, and the value of the threshold voltage (Vth) can be kept plus.

Specifically, it is possible to make the threshold voltage (Vth) not less than +1 V in the range where the multilayer portion width W1 is 40 nm to 2000 nm. Though not shown, in the region where the multilayer portion width W1 is not more than 40 nm, the threshold voltage (Vth) becomes not less than +2 V. In addition, even if the multilayer portion width W1 becomes several μm, the value of the threshold voltage (Vth) does not become minus. That is, even if the multilayer portion width W1 changed, it is possible to hold the value of the threshold voltage (Vth) plus, and the variation in the threshold voltages (Vth) can be suppressed to a large extent.

In addition, by recess etching which the upper portion of the undoped AlGaN layer 4 is etched, the threshold voltage (Vth) can be made (+) from (−). Here, in the region shown in FIG. 6, the threshold voltage (Vth) can be held at not less than 1 V.

On the other hand, in the nitride-based FET 90 of the comparative example shown by the broken line (b), the change in the threshold voltages (Vth) is very large, and the region in which the value of threshold voltage (Vth) can be kept plus is very narrow. Specifically, in the region where the multilayer portion width W1 is not more than 70 nm, the value of the threshold voltage (Vth) can be made plus. In the region where the width the multilayer portion W1 is larger than 70 nm, the value of the threshold voltage (Vth) becomes minus. That is, if the multilayer portion width W1 is changed by recess etching and so on, it becomes difficult to hold the value of the threshold voltage (Vth) plus, and thereby the variation in the threshold voltages (Vth) increases. In addition, the value of the threshold voltage (Vth) can not be made larger than that of the embodiment.

As described above, in the nitride-based FET of the embodiment, the source electrode 31, the drain electrode 32, the gate electrode 33, and the device region 34 are provided. The buffer layer 2, the undoped GaN layer 3, and the undoped AlGaN layer 4 on the silicon substrate 1 are formed with an MOCVD method. The protrusion portion 51 of the undoped GaN layer 3 is formed by second recess etching which the upper portion of the undoped GaN layer 3 is etched. The undoped AlGaN layer 4a is formed on the protrusion portion 51. The undoped AlGaN layer 4a is formed by first recess etching which the upper portion of the undoped AlGaN layer 4 is etched. The multilayer portion 7 is composed of the protrusion portion 51 of the undoped GaN layer 3, the undoped AlGaN layer 4a, and the insulating film 5. The trench portion 8 is formed by recess etching which the insulating film 5, the undoped AlGaN layer 4a, and the surface of the undoped GaN layer 3 are etched. The gate insulating film 6 is formed on the multilayer portion 7 and the trench portion 8. The gate electrode 33 is formed on the gate insulating film 6 so as to cover the trench portion 8. The film thickness of the insulating film 5 is set larger than that of the gate insulating film 6.

Consequently, while keeping the value of the threshold voltage (Vth) of the nitride-based FET 80 plus, the variation in the threshold voltages (Vth) can be reduced to a large extent. In addition, when a gate voltage larger than a predetermined value is applied to the gate electrode 33, as carriers are generated at the interface 9 of the undoped GaN layer 3 and the undoped AlGaN layer 4a, the ON resistance of the nitride-base FET 80 can be reduced.

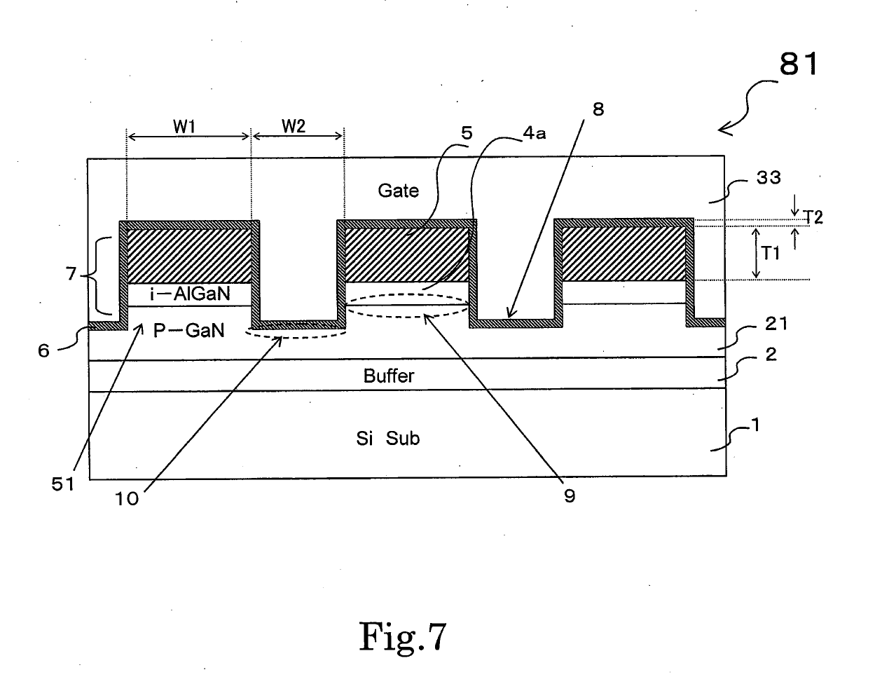

A nitride-based FET according to a second embodiment will be described with reference to the drawings. FIG. 7 is a schematic cross sectional view illustrating the nitride-based FET. In the embodiment, the GaN layer is composed of a P-type GaN layer, and the threshold voltage (Vth) is set larger.

Hereinafter, the same reference numerals are given to the same constituent portions as in the first embodiment, thereby the description thereof will be omitted, and only different portions will be described.

As shown in FIG. 7, in a nitride-based FET 81, a P-type GaN layer 21 is formed on the first main face (surface) of the buffer layer 2. At the region of the multilayer portion 7, the protrusion portion 51 of the P-type GaN layer 21, the undoped AlGaN layer 4a formed by recess etching which the undoped AlGaN layer 4 is etched, the insulating film 5, the gate insulating film 6, and the gate electrode 33 are stacked. The nitride-based FET 81 is an enhancement mode GaN HFET. The nitride-based FET 81 has high breakdown voltage characteristics (100 to 1000V, for example) and is applied to a high power switching device.

If the P-type GaN layer 21 is used in place of the undoped GaN layer, a threshold voltage (Vth) of the nitride-based FET 81 can be set larger than that of the first embodiment. If the threshold voltage (Vth) of the nitride-based FET 81 can be set not less than +3 V, for example, it becomes possible to satisfy specifications required for the power control field, such as a power converter circuit.

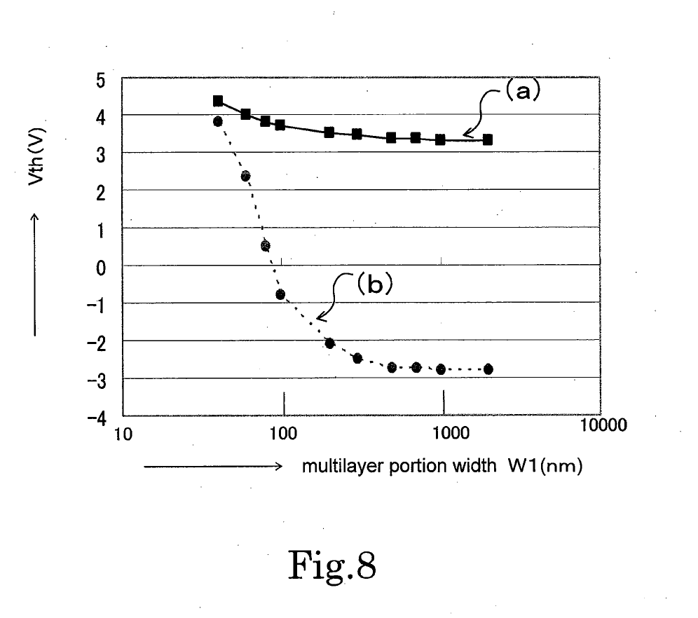

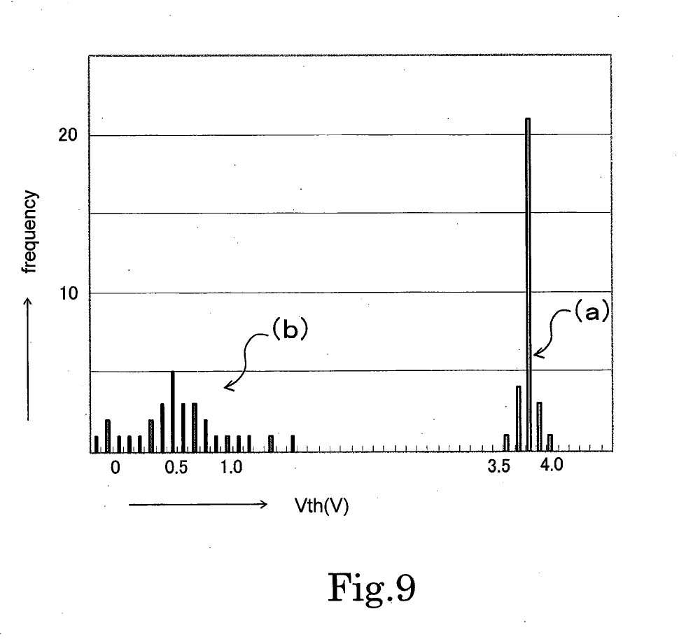

Next, DC characteristics of the nitride-based FETs will be described with reference to FIG. 8 and FIG. 9. FIG. 8 is a diagram illustrating the relation between a width of multilayer portion and a threshold voltage (Vth), and a solid line (a) in the figure is a relation diagram in the embodiment, and a broken line (b) in the figure is a relation diagram in a comparative example. FIG. 9 is a diagram showing the variation in the threshold voltages (Vth), and a histogram (a) in the figure is a distribution diagram in the embodiment, and a histogram (b) in the figure is a distribution diagram in the comparative example.

As shown in FIG. 8, in the nitride-based FET 81 of the embodiment shown by the solid line (a), even if the multilayer portion width W1 changes, the threshold voltage (Vth) of the nitride-based FET 81 changes extremely small, and the value of the threshold voltage (Vth) can be kept plus. Specifically, it is possible to make the threshold voltage (Vth) not less than +3 V in the range where the multilayer portion width W1 is 40 nm to 2000 nm. Though not shown, in the region where the multilayer portion width W1 is not more than 40 nm, the threshold voltage (Vth) becomes not less than +4 V. In addition, even if the multilayer portion width W1 becomes several μm, the threshold voltage (Vth) does not become minus.

On the other hand, in the nitride-based FET of the comparative example shown by the broken line (b), the change in the threshold voltages (Vth) is very large, and the region in which the value of threshold voltage (Vth) can be kept plus is very narrow. Specifically, in the region where the multilayer portion width W1 is not more than 90 nm, the value of the threshold voltage (Vth) can be made plus. In the region where the multilayer portion width W1 is larger than 90 nm, the value of the threshold voltage (Vth) becomes minus.

As shown in FIG. 9, in case that the multilayer portion width W1 is 80 nm, for example, in the nitride-based FET of the comparative example shown in the histogram (b) in the figure, an average value of the threshold voltages (Vth) is +0.5 V, and can not satisfy +3 V which is the predetermined specification value, and in addition, a standard deviation (a) as an index for variations is large as 0.77, and the variation of the threshold voltages (Vth) becomes extremely large. This result indicates that the margin of the threshold voltage (Vth) can not be set large for the processing condition, such as forming masks for recess formation and recess etching.

On the other hand, in case that the multilayer portion width W1 is 80 nm, for example, in the nitride-based FET 81 of the embodiment shown in the histogram (a) in the figure, an average value of the threshold voltages (Vth) is +3.82 V, and satisfies +3 V which is the predetermined specification value, and in addition, a standard deviation (a) as an index for variations is small as 0.068, and the whole values satisfy +3 V which is the predetermined specification value. This result indicates that the process margin can be set large for processing condition, such as forming masks for recess formation and recess etching.

As described above, in the nitride-based FET of the embodiment, the buffer layer 2, the P-type GaN layer 21, and the undoped AlGaN layer 4 on the silicon substrate 1 are formed with an MOCVD method. The protrusion portion 51 of the P-type GaN layer 21 is formed by second recess etching which the upper portion of the P-type GaN layer 21 is etched. On the protrusion portion 51, the undoped AlGaN layer 4a is formed by first recess etching which the upper portion of the undoped AlGaN layer 4 is etched. The multilayer portion 7 is composed of the protrusion portion 51 of the P-type GaN layer 21, the undoped AlGaN layer 4a, and the insulating film 5. The trench portion 8 is formed by recess etching which the insulating film 5, the undoped AlGaN layer 4a, and the surface of the P-type GaN layer 21 are etched. The gate insulating film 6 is formed on the multilayer portion 7 and the trench portion 8. The gate electrode 33 is formed on the gate insulating film 6 so as to cover the trench portion 8. The film thickness of the insulating film 5 is set larger than that of the gate insulating film 6.

Consequently, while keeping the value of the threshold voltage (Vth) of the nitride-based FET 81 at a plus value required for the power control field, the variation in the threshold voltages (Vth) can be reduced to a large extent. In addition, when a gate voltage larger than a predetermined value is applied to the gate electrode 33, as carries are generated at the interface 9 of the P-type GaN layer 21 and the undoped AlGaN layer 4a, the ON resistance of the nitride-based FET 81 can be reduced.

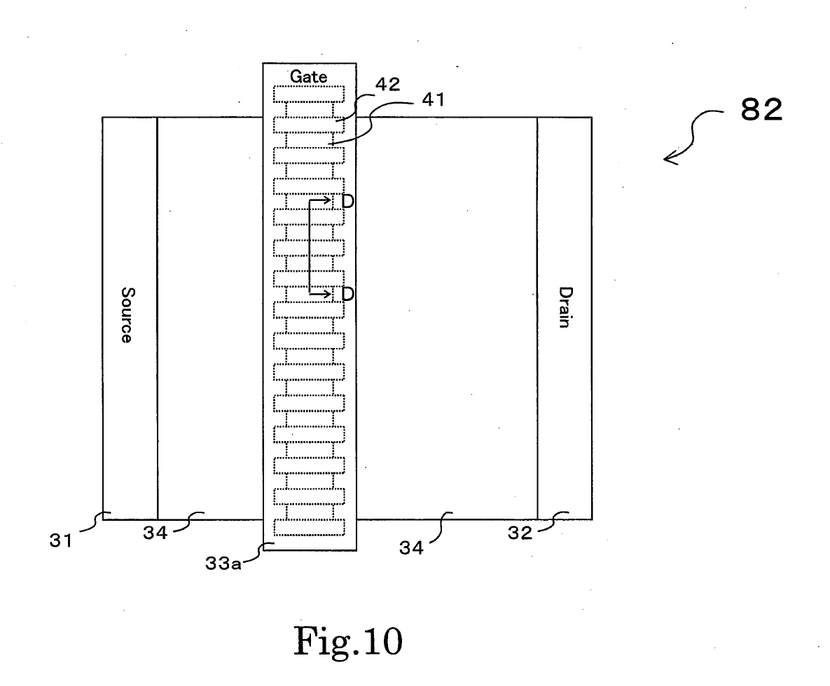

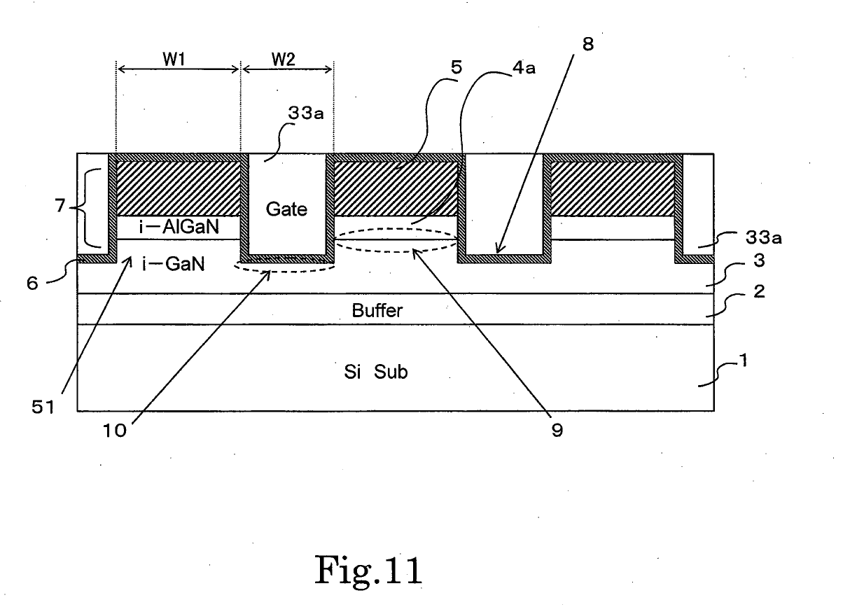

A nitride-based FET according to a third embodiment will be described with reference to the drawings. FIG. 10 is a plan view illustrating the nitride-based FET, and FIG. 11 is a schematic cross sectional view illustrating the nitride-based FET along a line D-D in FIG. 10. In the embodiment, a gate electrode is not provided on the multilayer portion.

Hereinafter, the same reference numerals are given to the same constituent portions as in the first embodiment, thereby the description thereof will be omitted, and only different portions will be described.

As shown in FIG. 10, in a nitride-based FET 82, the source electrode 31, the drain electrode 32, a gate electrode 33a, and the device region 34 are provided. The nitride-based FET 82 is an enhancement mode GaN HFET. The nitride-based FET 82 has high breakdown voltage characteristics (100 to 1000V, for example) and is applied to a high power switching device.

The gate electrode 33a is formed on the recess regions (second recess regions) 42 and on the device region 34. The gate electrode 33a is not formed on the recess regions (first recess regions) 41. The recess regions (second recess regions) 42 and the recess regions (first recess regions) 41 are provided so as to make the nitride-based FET 82a device of an enhancement mode (to make the nitride-based FET 82 normally OFF type).

As shown in FIG. 11, in the nitride-based FET 82, the gate electrode 33a is buried in the trench portion 8. Here, the height of the surface portion of the gate electrode 33a is set approximately equal to the height of the gate insulating film 5. A plurality of the buried gate electrodes 33a are bundled by a gate electrode (not shown) provided at the upper portion.

As described above, in the nitride-based FET of the embodiment, the source electrode 31, the drain electrode 32, the gate electrode 33a, and the device region 34 are provided. The buffer layer 2, the undoped GaN layer 3, and the undoped AlGaN layer 4 on the silicon substrate 1 are formed with an MOCVD method. The protrusion portion 51 of the undoped GaN layer 3 is formed by second recess etching which the upper portion of the undoped GaN layer 3 is etched. On the protrusion portion 51, the undoped AlGaN layer 4a is formed by first recess etching which the upper portion of the undoped AlGaN layer 4 is etched. The multilayer portion 7 is composed of the protrusion portion 51 of the undoped GaN layer 3, the undoped AlGaN layer 4a, and the insulating film 5. The trench portion 8 is formed by recess etching which the insulating film 5, the undoped AlGaN layer 4a, and the surface of the undoped GaN layer 3 are etched. The gate insulating film 6 is formed on the multilayer portion 7 and the trench portion 8. The gate electrode 33a is buried on the gate insulating film 6 so as to cover the trench portion 8, and the gate electrode 33a is not formed on the multilayer portion 7. A plurality of the buried gate electrodes 33a are bundled by the gate electrode (not shown) formed at the upper portion. The film thickness of the insulating film 5 is set larger than that of the gate insulating film 6.

Consequently, while keeping the value of the threshold voltage (Vth) of the nitride-based FET 82 plus, the variation in the threshold voltages (Vth) can be reduced to a large extent. In addition, when a gate voltage larger than a predetermined value is applied to the gate electrode 33a, as carriers are generated at the interface 9 between the undoped GaN layer 3 and the undoped AlGaN layer 4a, the ON resistance of the nitride-base FET 82 can be reduced.

In addition, in the embodiment, the insulating film 5 with a film thickness larger than that of the gate insulating film 6 is formed on the undoped AlGaN layer 4a, but the embodiment is not necessarily limited to this structure. The insulating film 5 on the undoped AlGaN layer 4a may be omitted, for example. In addition, the gate electrode 33a is buried in the trench portion 8 to the same height as the gate insulating film 5 of the multilayer portion 7, but the embodiment is not necessarily limited to this. The gate electrode 33a may be buried to the same height as the undoped AlGaN layer 4a, for example.

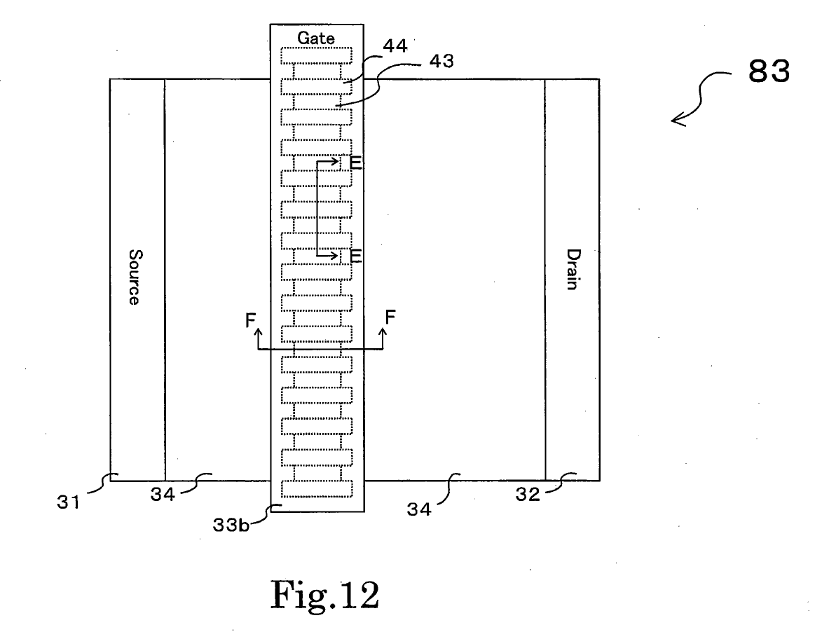

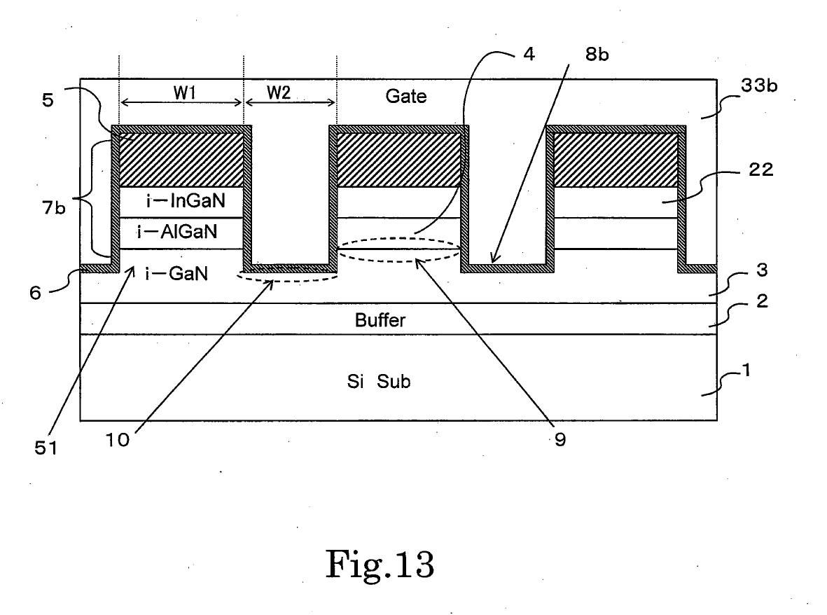

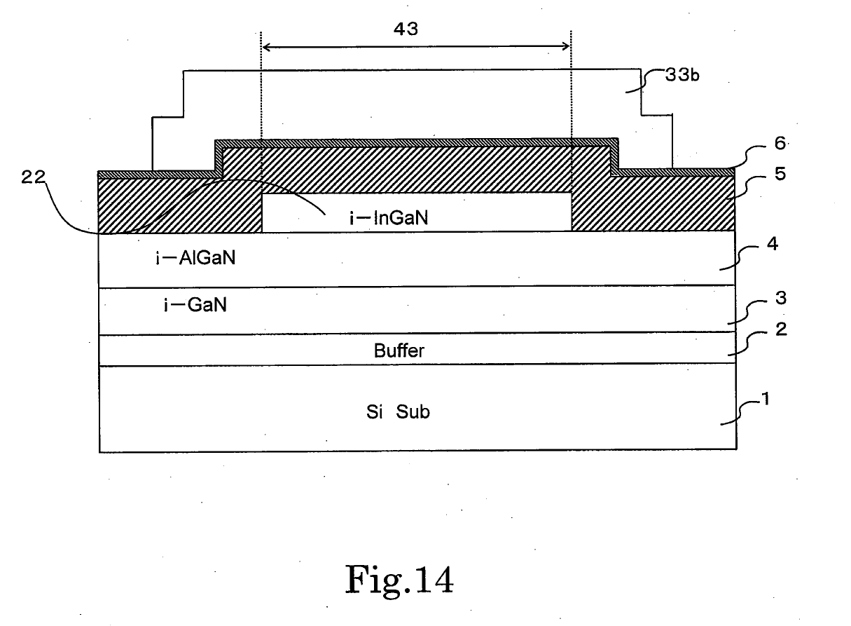

A nitride-based FET according to a fourth embodiment will be described with reference to the drawings. FIG. 12 is a plan view illustrating a nitride-based FET, FIG. 13 is a schematic cross sectional view illustrating the nitride-based FET along a line E-E in FIG. 12, and FIG. 14 is a schematic cross sectional view illustrating the nitride-based FET along a line F-F in FIG. 12. In the embodiment, a GaN family HFET is made a device of an enhancement mode by providing an InGaN layer on the AlGaN layer.

Hereinafter, the same reference numerals are given to the same constituent portions as in the first embodiment, thereby the description thereof will be omitted, and only different portions will be described.

As shown in FIG. 12, in a nitride-based FET 83, the source electrode 31, the drain electrode 32, a gate electrode 33b, and the device region 34 are provided. The nitride-based FET 83 is an enhancement mode GaN HFET. The nitride-based FET 83 has a high breakdown voltage characteristics (100 to 1000 V, for example), and is applied to a high power switching device.

Immediately under the gate electrode 33b, non-recess regions 43 having a rectangular structure, and recess regions 44 having a rectangular structure are provided. Here each of the recess regions 44 has a construction in which a crosswise direction size of the recess regions 44 is longer than that of the non-recess region 43, and a long end portion side of the recess regions 44 protrudes from those of the non-recess region 43, respectively. The recess regions 44 are arranged at the upper end portion and the lower end portion in the figure. The non-recess regions 43 and the recess regions 44 are arranged alternately and periodically in the up-and-down direction in the figure. At the both sides of the non-recess region 43 having a stripe shaped structure, the recess regions 44 having a stripe shaped structure are arranged, each of which has end portions protruding from those of the non-recess region 43. By arranging the recess regions 44 with a construction like this, it is possible to suppress the mutual interference between the non-recess regions 43 which function as active regions.

The nitride-base FET 83 is made a device of an enhancement mode by providing the non-recess regions 43 and the recess regions 44 immediately under the gate electrode 33b (the detail will be described later). Here, the recess region 44 is formed by etching vertically the device region 34 with an RIE method using BCl₃ plasma, for example.

As shown in FIG. 13, in the nitride-based FET 83, the buffer layer 2 is formed on the first main face (surface) of the silicon substrate 1 which is a semiconductor substrate. The undoped GaN layer 3 is formed on the first main face (surface) of the buffer layer 2. At the region of a multilayer portion 7b, the protrusion portion 51 of the undoped GaN layer 3, the undoped AlGaN layer 4, an undoped InGaN layer 22, the insulating film 5, the gate insulating film 6, and the gate electrode 33b are lamination formed.

Here, the non-recess region 43 shown in FIG. 12 is composed of the protrusion portion 51 of the undoped GaN layer 3, the undoped AlGaN layer 4, the undoped InGaN layer 22, and the insulating film 5, and corresponds to the multilayer portion 7b having the multilayer portion width W1. At the recess region 44 shown in FIG. 12, the insulating film 5, the undoped InGaN layer 22, the undoped AlGaN layer 4 and the surface of the undoped GaN layer 3 are recessed by selective etching, and the recess region 44 corresponds to a trench portion 8b with the trench width W2.

The gate insulating film 6 is formed on the multilayer portion 7b and the trench portion 8b. On the gate insulating film 6, the gate electrode 33b is formed so as to cover the trench portion 8b. The undoped InGaN layer 4 is formed using an MOCVD method, for example.

As shown in FIG. 14, at the non-recess region 43, the buffer layer 2, the undoped GaN layer 3, the undoped AlGaN layer 4, the undoped InGaN layer 22, the insulating film 5, the gate insulating film 6 and the gate electrode 33b are stacked on the first main face (surface) of the silicon substrate 1. At the both end portions of the non-recess region 43 in the gate stripe direction, the buffer layer 2, the undoped GaN layer 3, the undoped AlGaN layer 4, the insulating film 5, the gate insulating film 6 and the gate electrode 33b are stacked on the first main face (surface) of the silicon substrate 1.

The undoped InGaN layer 22 formed on the undoped AlGaN layer 4 generates distortion in the reverse direction of the undoped AlGaN layer 4. The thickness of the undoped InGaN layer 22 is set so that the two dimensional electron gas (2DEG) which is generated at the interface 9 between the undoped AlGaN layer 4 and the undoped GaN layer 3 disappears when a gate voltage is not applied.

Consequently, when a relatively small positive voltage is applied to the gate electrode 33b, an inverted channel layer is generated at the interface 10, and the transistor becomes in ON state. In this time, as the insulating film 5 with a film thickness larger than that of the gate insulating film 6 is provided at the upper portion of the multilayer portion 7b, carriers are not generated at the interface 9 because of being not affected by the voltage given from the gate electrode 33b. Then, when the value of the gate voltage increases, under influence of by the potential of the gate electrode 33b from the side surface of the multilayer portion 7b, carries are generated also at the interface 9. As the interface 9 is a good epitaxial interface, the mobility therein is high, and accordingly, it is possible to greatly reduce the ON resistance of the nitride-based FET 83, by giving a voltage larger than a voltage with which carries can be generated at the interface 9 to the gate electrode 33b.

In addition, the undoped GaN layer 3 is used in the embodiment, but it may be doped with p-type or n-type dopant so as to control the threshold value. In addition, the gate electrode 33b is not provided on the multilayer portion 7b, but may be buried in the trench portion 8b instead.

As described above, in the nitride-based FET of the embodiment, the source electrode 31, the drain electrode 32, the gate electrode 33b, and the device region 34 are provided. The buffer layer 2, the undoped GaN layer 3, the undoped AlGaN layer 4, and the undoped InGaN layer 22 on the silicon substrate 1 are formed with an MOCVD method. The protrusion portion 51 of the undoped GaN layer 3 is formed by recess etching which the upper portion of the undoped GaN layer 3 is etched. The undoped AlGaN layer 4 and the undoped InGaN layer 22 are formed on the protrusion portion 51. The multilayer portion 7b is composed of the protrusion portion 51 of the undoped GaN layer 3, the undoped AlGaN layer 4, the undoped InGaN layer 22, and the insulating film 5. The trench portion 8b is formed by recess etching which the insulating film 5, the undoped InGaN layer 22, the undoped AlGaN layer 4, and the surface of the undoped GaN layer 3 are etched. The gate insulating film 6 is formed on the multilayer portion 7b and the trench portion 8b. The gate electrode 33b is formed on the gate insulating film 6 so as to cover the trench portion 8b. The undoped InGaN layer 22 generates distortion in the reverse direction of the undoped AlGaN layer 4. The film thickness of the insulating film 5 is set larger than that of the gate insulating film 6.

Consequently, while keeping the value of the threshold voltage (Vth) of the nitride-based FET 83 plus, the variation in the threshold voltages (Vth) can be reduced to a large extent. In addition, when a gate voltage larger than a predetermined value is applied to the gate electrode 33b, as carriers are generated at the interface 9 between the undoped GaN layer 3 and the undoped AlGaN layer 4, the ON resistance of the nitride-base FET 83 can be reduced.

In the embodiment, the enhancement mode GaN family HFET is applied to a power device with high breakdown voltage characteristics, but can be applied to a high frequency device for microwave or millimeter wave application. In addition, in order to reduce current collapse and to increase high breakdown voltage, a dual field plate structure may be employed for the enhancement mode GaN family. The dual field plate structure means a structure where a gate electrode is extended to a drain side and a source electrode is extended to the drain side across the gate electrode.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nitride-based FET, comprising:
a semiconductor substrate;
a first nitride semiconductor layer formed directly or via a buffer layer on the semiconductor substrate;
a second nitride semiconductor layer formed on the first nitride semiconductor layer, the second nitride semiconductor layer having a first portion and a second portion with a concave structure whose thickness is smaller than that of the first portion;
a multilayer portion having a stripe shaped structure, the multilayer portion stacking a protrusion portion of the first nitride semiconductor layer whose thickness larger than that of an ambient portion, the second portion of the second nitride semiconductor that is formed on the protrusion portion, and an insulating film that is formed above the protrusion portion via the second portion of the second nitride semiconductor layer;
trench portions having a stripe shaped structure respectively, the trench portions being adjacent to both sides of the multilayer portion so as to expose a surface of the first nitride semiconductor layer;
a gate insulating film formed on a side surface of the multilayer portion, on an upper surface of the multilayer portion and bottom surfaces of the trench portions, and having a film thickness smaller than that of the insulating film;
a gate electrode formed on the gate insulating film; and
a source electrode and a drain electrode being arranged to face each other across the gate electrode.

2. The nitride-based FET according to claim 1, wherein the nitride based FET is an enhancement mode field effect transistor.

3. The nitride-based FET according to claim 1, wherein the first nitride semiconductor layer is an undoped GaN layer, and the second nitride semiconductor layer is an undoped AlGaN layer.

4. The nitride-based FET according to claim 3, wherein the second nitride semiconductor layer is composed of Al_{0.25}Ga_{0.75}N.

5. The nitride-based FET according to claim 1, wherein the first nitride semiconductor layer is a P-type GaN layer, and the second nitride semiconductor layer is an undoped AlGaN layer.

6. The nitride-based FET according to claim 1, wherein the semiconductor substrate is a silicon substrate.

7. The nitride-based FET according to claim 1, wherein the insulating film is composed of an SiO₂ film or an SiOC film.

8. The nitride-based FET according to claim 1, wherein the gate insulating film is composed of an SiN film, a Ta₂O₅ film, a HfO₂ film, or an Al₂O₃ film.

9. The nitride-based FET according to claim 1, wherein the multilayer portion and the trench portion are arranged alternately and repeatedly.

10. The nitride-based FET according to claim 1, wherein the gate electrode is composed of a P-type polycrystalline silicon film, a laminated Ni/Au film, or a laminated Ti/Pt/Au film.

11. The nitride-based FET according to claim 1, wherein the buffer layer is formed by laminating a film composed of AlN/GaN repeatedly.

12. A nitride-based FET, comprising:
a semiconductor substrate;
a first nitride semiconductor layer formed directly or via a buffer layer on the semiconductor substrate;
a second nitride semiconductor layer formed on the first nitride semiconductor layer, the second nitride semiconductor layer having a first portion and a second portion with a concave structure whose thickness is smaller than that of the first portion;
a multilayer portion having a stripe shaped structure, the multilayer portion stacking a protrusion portion of the first nitride semiconductor layer whose thickness larger than that of an ambient portion, the second portion of the second nitride semiconductor that is formed on the protrusion portion, and an insulating film that is formed above the protrusion portion via the second portion of the second nitride semiconductor layer;
trench portions having a stripe shaped structure respectively, the trench portions being adjacent to both sides of the multilayer portion so as to expose a surface of the first nitride semiconductor layer;
a gate insulating film formed on a side surface of the multilayer portion, on an upper surface of the multilayer portion and bottom surfaces of the trench portions, and having a film thickness smaller than that of the insulating film;
a gate electrodes buried in the trench portion via the gate insulating film; and
a source electrode and a drain electrode being arranged to face each other across the gate electrode.

13. The nitride-based FET according to claim 12, wherein the nitride-based. FET is an enhancement mode field effect transistor.

14. The nitride-based FET according to claim 12, wherein the first nitride semiconductor layer is an undoped GaN layer, and the second nitride semiconductor layer is an undoped AlGaN layer.

15. The nitride-based FET according to claim 12, wherein the semiconductor substrate is a silicon substrate.

16. A nitride-based FET, comprising:
a semiconductor substrate;
a first nitride semiconductor layer formed directly or via a buffer layer on the semiconductor substrate;
a second nitride semiconductor layer formed on the first nitride semiconductor layer;
a third nitride semiconductor layer which formed on the second nitride semiconductor layer;
a multilayer portion having a stripe shaped structure, the multilayer portion stacking a protrusion portion of the first nitride semiconductor layer whose thickness is larger than that of an ambient portion, the second nitride semiconductor layer on the protrusion portion, the third nitride semiconductor layer that is formed above the protrusion portion via the second nitride semiconductor layer, and an insulating film that is formed above the protrusion portion via the second and third nitride semiconductor layers;
trench portions having a stripe shaped structure respectively, the trench portions being adjacent to both sides of the multilayer portion so as to expose a surface of the first nitride semiconductor layer;
a gate insulating film which formed on a side surface of the multilayer portion, on an upper surface of the multilayer portion and bottom surfaces of the trench portions, and having a film thickness smaller than that of the insulating film;
a gate electrode formed on the gate insulating film; and
a source electrode and a drain electrode being arranged to face each other across the gate electrode.

17. The nitride-based FET according to claim 16, wherein the nitride-based FET is an enhancement mode field effect transistor.

18. The nitride-based FET according to claim 16, wherein the first nitride semiconductor layer is an undoped GaN layer, the second nitride semiconductor layer is an undoped AlGaN layer, and the third nitride semiconductor layer is an undoped InGaN layer.

19. The nitride-based FET according to claim 16, wherein the semiconductor substrate is a silicon substrate.
